(19) United States
(12) Patent Application Publication
(10) Pub. No.: US 2011/0278742 A1
(43) Pub. Date: Nov. 17, 2011

(54) Circuitry and Method for Encapsulating the Same

(76) Inventors: Burkhard Schelle, Oberhausen (DE); Robert Klieber, Dortmund (DE)

(21) Appl. No.: 12/674,080

(22) PCT Filed: Aug. 7, 2008
(86) PCT No.: PCT/EP2008/006526

§ 371 Date: Aug. 2, 2011

(30) Foreign Application Priority Data
Aug. 31, 2007 (DE) 10 2007 041 229.2

(51) Int. Cl. H01L 23/49; H01L 21/56

(52) U.S. Cl. 257/784; 438/127; 257/E23.024; 257/E21.502

(57) ABSTRACT

A circuitry comprises a substrate with a terminal region, a semiconductor device with a contact terminal, a bond wire connecting the terminal region to the contact terminal and a solder glass encapsulating material. The solder glass encapsulating material is mounted on the semiconductor device with the bond wire, so that at least the bond wire is hermetically enclosed. The substrate has a substrate material with a first coefficient of thermal expansion, the semiconductor device has a device material with a second coefficient of thermal expansion and the bond wire has a bond wire material with a third coefficient of thermal expansion. The solder glass encapsulating material has a coefficient of thermal expansion adjusted to a predefined value with regard to the second and third coefficients of thermal expansion.

### CROSS-REFERENCE TO RELATED APPLICATIONS

This application is a national phase entry of PCT Patent Application No. PCT/EP2008/006526, filed 07 Aug. 2008, which claims priority to German Patent Application No. 102007041229.2-33, filed 31 Aug. 2007, each of which is incorporated herein by reference.

### BACKGROUND OF THE INVENTION

The present invention relates to a method for protecting semiconductor chips and bond wires mounted thereto and in particular their encapsulation.

In many applications, bond wires are used for electrically connecting microelectronic devices. In contrast to conventional connections, bond wires are mostly thin wires connecting integrated circuits to electrical terminals. Due to their extremely low thickness, bond wires are very sensitive to environmental influences.

Hence, there is a need for providing circuitries having a hermetic encapsulation, wherein a thermally stable encapsulation is ensured between the device and a substrate. In particular, there is a need for a method by which electric circuit chips can be protected easily and in a cost-effective manner against environmental influences.

### SUMMARY

According to an embodiment, a circuitry may have a substrate having a terminal region, the substrate material having a first coefficient of thermal expansion; a semiconductor device having a contact terminal, the device material having a second coefficient of thermal expansion; a bond wire connecting the terminal region to the contact terminal, the bond wire material having a third coefficient of thermal expansion; and a solder glass encapsulating material mounted to the semiconductor device with the bond wire, such that at least the bond wire is hermetically enclosed, wherein the solder glass encapsulating material has a coefficient of thermal expansion and is composite such that the coefficient of thermal expansion is adjusted to a predefined value with regard to the second and third coefficients of thermal expansion.

According to another embodiment, a method for producing a glass-encapsulated bond wire connection may have the steps of: providing a substrate having a terminal region, the substrate material having a first coefficient of thermal expansion; arranging a semiconductor device having a contact terminal on the substrate, the device material having a second coefficient of thermal expansion; connecting the contact terminal to the terminal region with a bond wire, the bond wire material having a third coefficient of thermal expansion; and forming a solder glass encapsulating material such that at least the bond wire is hermetically enclosed, wherein the solder glass encapsulating material has a coefficient of thermal expansion and is composite such that the coefficient of thermal expansion is adjusted to a predefined value with regard to the second and third coefficients of thermal expansion.

### BRIEF DESCRIPTION OF THE DRAWINGS

Embodiments of the present invention will be detailed subsequently referring to the appended drawings, in which:

FIG. 1 is a cross-sectional view of a circuitry according to an embodiment of the present invention;

FIG. 2 is a top view of the circuitry of FIG. 1; and

FIG. 3 is a cross-sectional view of a device fixed on a substrate and protected via solder glass.

### DETAILED DESCRIPTION OF THE INVENTION

With regard to the subsequent description, it should be noted that the same or equal functional elements have the same reference numbers in the different embodiments and thus descriptions of these functional elements are interchangeable in the different subsequently illustrated embodiments.

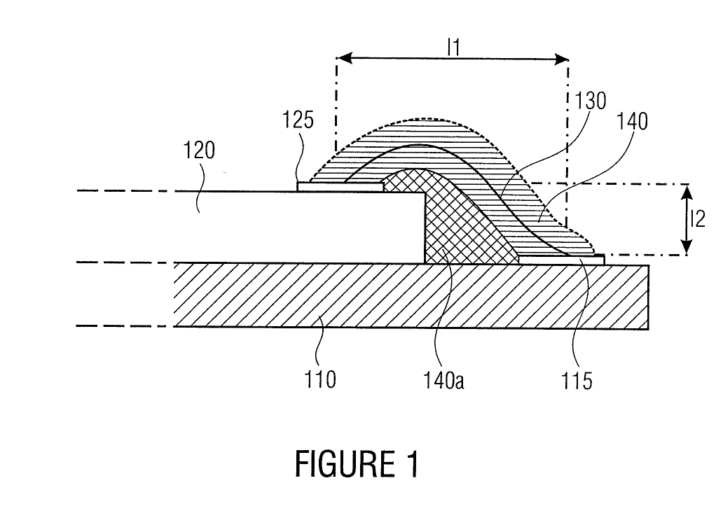

FIG. 1 shows a cross-sectional view of a substrate 110 having a terminal region 115 and a semiconductor device 120 arranged on the substrate 110 and having a contact terminal 125, wherein the contact terminal is arranged on a side of the semiconductor device (device) 120 opposite the substrate 110. Further, a bond wire 130 connects the terminal region 115 to the contact terminal 125 by a bond connection, and the bond wire 130 is hermetically enclosed by a solder glass encapsulating material (solder glass material) 140. The (average) lateral distance between a contact of the bond wire 130 with the contact terminal 125 and a contact of the bond wire 130 with the terminal region 115 comprises a length 11 (lateral distance), while the bond wire 130 spans a level difference 12 between the terminal region 115 and the contact terminal 125, wherein the level difference 12 extends perpendicularly to the lateral extension of the substrate 110. Bond wire connections can be used, for example, for spanning a large level difference in contacting devices. For example, the level difference 12 can be more than 10 or more than 50% of the length or distance 11. Further, it is possible that 11>12. However, with regard to process technology, it can be advantageous when there is no level difference 12 or when the level difference 12 is less than 10% of the length 11.

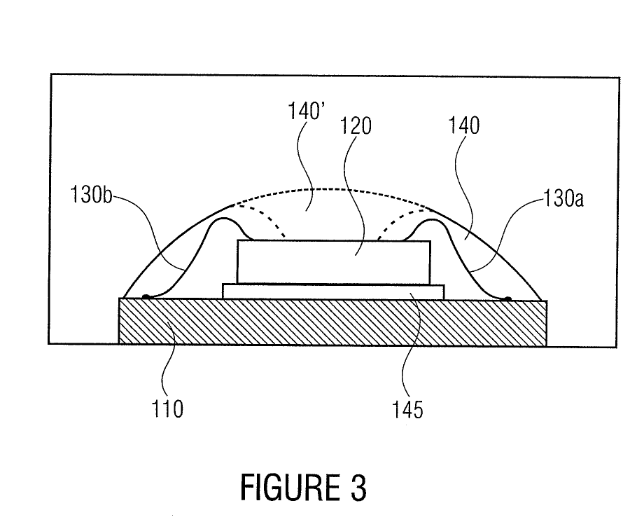

In further embodiments, the solder glass material 140 comprises a larger region around the bond wire 130 and can fill, for example, a gap 140a between the bond wire 130 and the substrate 110 on the one hand and between the bond wire 130 and the device 120 on the other hand (one example of this is shown in FIG. 3).

Bond wires mostly connect terminals of substrates/leadframes/integrated circuits (pins) to terminals of a silicon chip (so-called die), however connections between two or more chips are also possible. Bond wires comprise, for example, gold or gold alloys but also aluminum, and may also have a silicon component. Possible diameters of bond wires generally depend on the material, so that different values for the diameters can result, for example in a range of 5 to 700 μm or also in the range between 10 and 100 μm or between 25 and 50 μm. The diameters of bond wires can, however, also be in a range of 100 to 500 μm. If a current carrying capacity of such wires is not sufficient, generally so-called multiple bonds are implemented via several wires. However, it is also possible that bonding is implemented by using metal rails or elongated metal dies having, for example, a diameter or a thickness of 500 μm to 5 mm or between 1 and 3 mm. In power electronics, mostly pure aluminum bond wires are used, having, for example, an aluminum component of more than 59%, while in discrete semiconductors frequently pure gold is used. Copper wires are also possible, although their usage is significantly lower compared to the usage of gold and aluminum. Further possible materials comprise tungsten, platinum and silver. Methods for bonding can, for example, comprise thermal compression (combination of pressure and higher temperature), thermosonic bonding (combination of heating and ultrasound) or ultrasonic bonding. In this method, the bonding action results with the help of the bonding force and the ultrasonic effect. Bond wires are particularly used where an electrical connection is not only to be implemented on one level, but contact terminals are also to be connected on several levels. Thereby, measured with regard to the length of the bond wire 130, level differences of more than 10% or more than 50% can be realized.

According to the present invention, solder glasses are only used for encapsulation for overcoming extremely differing coefficients of thermal expansion (CTE) between different materials. Solder glasses are glass materials having a low softening temperature which are particularly suitable for sealing and connecting (soldering method). Solder glass exhibits a softening temperature lying significantly below a softening temperature of normal glass—for example solder glasses already soften at 400° C. Solder glass materials can be deposited in powder or liquid form on an object to be protected, and the object to be protected can comprise, for example, a chip, an assembly or a complete printed circuit board. Solder glass materials have the advantage that they are very hard, for example at room temperature and that they have, depending on the glass type or depending on the composition, a coefficient of thermal expansion that is adjustable in a very wide range and which can, for example, be close to the coefficient of thermal expansion of the silicon chip or the substrate or the coefficient of thermal expansion of aluminum or another bonding material. A further advantage of solder glass materials is, for example, that they have a high resistance to chemicals and that their melting point can be adjusted, for example in a range of 300° C. to 700° C. Due to their low coefficient of thermal expansion and their high hardness (e.g. at room temperature), solder glass materials are inventively used for the protection of bond wires.

It can be advantageous when the solder glass material is selected such that it has a low melting temperature, a low coefficient of thermal expansion and further a minimum hardness. Thereby, on the one hand, it is obtained that, when depositing the solder glass material, the thermal stress on the semiconductor device is as low as possible. Additionally, the coefficient of thermal expansion can be as close as possible to that of the substrate and finally the obtained hardness ensures that the connection has sufficient stability.

With a respective selection of the composition, the degree of hardness of solder glass materials for a certain (operating) temperature range can be used for balancing thermal tensions between the individual components, without the occurrence of thermal damage or destruction of the electrical connection (for example by mechanical stress of the bond wire connection). Further, mechanical stresses on the chip can be avoided that, in turn, could affect the electrical properties. Additionally, solder glass materials can also be used with regard to temperature fluctuations (for example from room temperature up to 250° C. or up to the melting point, which can start from 350° C. onwards or that can, for example, be 600° C. or 700° C.), and can also compensate the occurring stresses also in several cycles of temperature fluctuations. However, only specific chips can resist temperatures up to a range of 600° C., and from 700° C. onwards almost all chips show malfunctions. Thus, solder glass connections also serve as a buffer layer compensating for the different thermal expansions. Hence, according to the invention, they can be used to protect or connect glass, ceramics or metals such that thermal stresses or thermal damage can be minimized.

Processing the solder glass materials can take place, for example, at a temperature where the solder glass material has a viscosity in a range, for example, of 10⁴ to 10⁶ dPa*s which is typically in the temperature range of T=350−700° C. A first type of solder glass materials behaves like traditional glass, so that the characteristics above the softening temperature do not differ from the characteristics below the softening temperature. The second type is crystallizing solder glass materials, i.e. they change to a ceramic-like polycrystalline structure during softening. During crystallization, the viscosity increases by several orders of magnitude, such that further flow is suppressed. This time-dependent viscosity behavior does not exist in the first type of solder glass materials.

The production of solder glass materials having a very low softening temperature is limited by the fact that lowering the softening temperature is generally accompanied by an increase of the coefficient of thermal expansion. However, this effect is less distinct in a second class of solder glass materials (showing a crystallization phase). The increase of the coefficient of thermal expansion can be avoided or suppressed, for example, by adding respective additives (non-active) having a low or even negative coefficient of expansion, such as ZrSiO₄ or β-eucryptites. These composite solder glass materials 140 are inventively used for producing stable glass connections. Since the additives reduce fluidity during softening, they can only be added to a limited extent. When considering the materials that are to be connected, suitable solder glass materials are generally selected with regard to the following criteria:

1. maximum tolerable softening temperature,

2. coefficients of thermal expansion of the materials that are to be connected,

3. maximum occurring temperature up to which the solder glass material is to remain stable and

4. chemical behavior.

For obtaining a satisfactory connection, the solder glass material 140 should be sufficiently fluid and wetting for being able to connect the parts to be connected without any problems (as it is also the case in conventional solder connections, for example).

However, the fluidity and wetting ability are temperature- and time-dependent; the higher the temperature, the less time is necessitated for a sufficient flow and vice versa. Thus, frequently, when soldering at high temperatures, only very little time is necesitated, while at low temperatures (i.e. at viscosities of more than 10⁷ dPa*s) a long time is necessitated for obtaining sufficient fluidity.

Between the coefficients of thermal expansion of the individual components that are to be connected or sealed to each other, inventively, the solder glass material 140 can operate as a buffer layer for obtaining connections that are stable and firm within wide limits. As a rule, it can apply that the coefficients of thermal expansion of the solder glass material 140 differ by a factor of Δα=0.5 . . . 5.0×10⁻⁶/K or are by 0.5 . . . 1.0×10⁻⁶/K smaller than the coefficients of thermal expansion of the materials to be connected. Such a difference between the coefficients of thermal expansion can occur in all materials of the different components. When using solder glass materials having a crystallization phase, it has to be considered that the coefficients of thermal expansion are only valid when certain conditions are maintained, wherein the conditions relate to a specific soldering method. Changing the soldering method, in particular changing the soldering temperature and the soldering time, can have an influence on the relation between the glass and crystalline phase and can thus cause a change of the coefficients of thermal expansion, which results in a mismatch between the individual components.

Glass seals produced with such solder glass materials can be stressed up to a temperature of approximately 50 Kelvin below the transformation temperature or softening temperature of the solder glass material 140. Generally, the maximum possible temperature depends, however, on the type and melting point of the deposited crystal and additionally on the properties of the remaining glass phase.

Up to the maximum possible usage temperature, solder glass materials are stable with regard to humidity and gas seal. Their electrical insulator properties are better than in may other technical glasses and are thus particularly suited also for temperature-resistant insulations.

Solder glass materials are specific technical glasses. General technical glasses can be classified as follows:

(A): borosilicate glasses

(B): alkaline earth alumino silicate glasses

(C): alkali lead silicate glasses

(D): alkali alkaline earth silicate glasses

Borosilicate glasses of group (A) have a characteristic composition of silicon dioxide (SiO₂) and boric acid (B₂O₃), wherein typically the boric acid component is more than 8%.

The boric acid component has a great influence on the glass properties. Apart from high resistance against many influences—as long as the boric acid content remains below a maximum component of 13%—there are different compositions having only a very low chemical resistance. Consequently, the following classifications are possible:

First, these are the alkaline earth-free borosilicate glasses, where the boric acid component is in a range between 12 and 13% and the silicon dioxide component exceeds 80%. These glasses have a high chemical resistance and at the same time a low coefficient of thermal expansion (for example at 3.3×10⁻⁶/K).

In a further group there are the borosilicate glasses containing alkaline earths, wherein the silicon dioxide component is at approximately 75%, and further containing approximately 8 to 12% boric acid. Further, these glasses include up to 5% alkaline earths and aluminum oxide (Al₂O₃). These glasses are slightly softer than the alkaline earth borosilicate glasses and have, for example, a coefficient of thermal expansion that can be in a range of 4.0 to 5.0×10⁻⁶/k. Further, these glasses have a high chemical resistance.

Finally, there are the borosilicate glasses having a high boric acid component. These glasses, for example, have a boric acid component that can be between 15 and 25% and further a silicon dioxide component that can lie between 65 and 75%. Further, these glasses have a smaller component of alkaline materials and aluminum dioxide that are added as additional components. These borosilicate glasses have a low softening point and a low coefficient of thermal expansion. They can seal or encapsulate metals having a coefficient of expansion that can lie in a region of tungsten and molybdene. Further, these glasses show a high electrical insulation effect, which is desirable for many applications. The increased boric acid component results, however, in a reduction of the chemical resistance and thus chemical substances can more easily attack these glasses.

The above-mentioned group (B) covers glasses that are typically free of alkali oxides and have, for example, an aluminum dioxide component in a range between 15 and 25% and where the silicon oxide component can lie between 52 and 60%. Further, these glasses have an alkaline earths component of approximately 15%. These alkaline earth aluminosilicate glasses have a very high transformation temperature (softening temperature) and are typically used in halogen lamps, display glasses and high-temperature thermometers.

Alkali-lead silicate glasses of group (C) typically have a lead oxide component of more than 10%. For example, lead glasses containing lead oxide in the range of 20 to 30% and additionally 54 to 58% silicon dioxide and approximately 14% alkaline materials have very good insulating characteristics.

Finally, in group (D), the alkali alkaline earth silicate glasses have a component of 15% of alkali materials (normally Na₂O), 13 to 16% alkaline earths (CaO+MgO), 0 to 2% Al₂O₃ and approximately 71% SiO₂. A typical example of these glasses is normal window glass.

For solder glass materials, for example, alumoborosilicate glasses (glasses with a very low alkali metal oxide component), lead borate glasses and lead-free borate oxides are used. In lead borate glasses, the softening temperature can lie approximately between 410 and 570° C., wherein the softening temperature can be lowered by lowering the boric acid component, replacing lead by alkali materials (Li, Na, K) or replacing boric acid by aluminum. The softening temperature can further be increased by replacing lead by alkaline earth oxides (Mg, Zn, Ca, Ba, Sr) or boric acid by Zr and Ti (Ti>Zr). The solder glass materials used here are merely specific examples, wherein further forms and compositions of solder glass materials are possible. Solder glass materials can be both transparent and opaque. In particular, it is also possible to specifically filter out, by the solder glass material or by additives, a color or frequency range of incident radiation (e.g. an infrared or ultraviolet range or also the visible range).

Possible solder glass materials have, for example, a coefficient of thermal expansion within a range of 2 ppm/K to 25 ppm/K and, for example, between 3.6 ppm/K up to 8.9 ppm/K within a temperature range of 20 to 250° C. and a melting temperature between 300 and 700° C.

However, solder glass materials are not only suitable for the above-mentioned protection of bond wires, but can also be used as adhesive material, for example for mounting or holding a chip on a substrate 110. Compared to normally used adhesives, such as epoxys and polyamides, solder glass materials have the advantage that the solder glass material 140 can have a coefficient of thermal expansion matching the substrate 110 or the silicon chip, or which is adjustable correspondingly. Further, compared to conventionally used adhesives, solder glass materials have a significantly higher temperature resistance, which is why they are particularly suitable for applications subject to higher thermal stresses. Solder glass materials can be used, for example, as chip adhering materials that are used for temperatures above 200° C.

The solder glass material 140 can be deposited in liquid form onto the chip and the bond wires and then be hardened by baking (and annealing). In this way, individual chips, complete assemblies or also complete printed circuit boards can be filled and protected from environmental influences. In particular, the devices, or the bond wires, can be protected from shocks, chemicals, radiation, etc. Additionally, due to their hardness, the solder glass materials give the bond wires additional mechanical support. Depending on the composition used for the solder glass material 140, the hardened material can become very hard or also flexible and soft after baking, wherein, according to the invention, the solder glass material 140 is very hard.

Thus, the applicability of solder glass materials also relates to the protection of chips or electrical devices and also to the protection of the electrical connection from environmental influences, such as shocks, chemicals, radiation and, in particular, for temperatures up to the melting point of the glass. Further, it is advantageous that solder glass materials can be selected in their composition such that the melting point of the glass can be adjusted across a wide range and thus can be adjusted to an operating temperature range of the semiconductor device 120. Thus, changes in the chip (e.g. due to amended dopings or deformed metallization) changing the physical characteristics can be avoided.

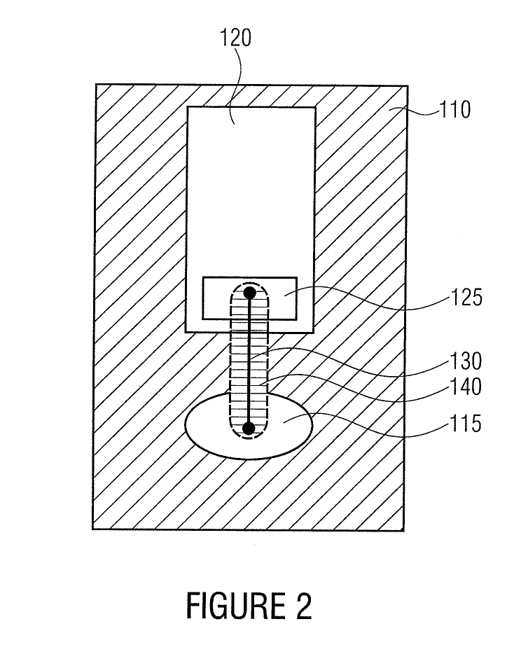

FIG. 2 shows the top view of the arrangement of FIG. 1, wherein a main side of the substrate 110 is shown, on which the semiconductor device 120 is arranged. Further, the contact terminal 125 and the contact region 115 are shown that are electrically connected to each other via the bond wire 130. As in FIG. 1, the solder glass material 140 protects the bond wire 130 from external influences and/or provides improved mechanical support. In this embodiment, the specific design of the solder glass material 140 can also be varied such that the solder glass material 140 can also be formed in a larger region around the bond wire 130. For avoiding corrosion of the contact terminal 125 of the semiconductor device 120 and also corrosion of the terminal region 115 on the substrate 110, it can be advantageous to deposit the solder glass material 140 such that the contact terminal 125 and the terminal region 115 are also hermetically protected by the solder glass material 140.

The device 120 arranged on the substrate 110 can have different shapes. It can be square, round or oval and contact terminals 125 can be formed on different sides of the device. For example in the top view, as shown in FIG. 2, bond wire connections can also be implemented towards the right, the left or the top, or several bond wire connections towards the bottom can be combined with several bond wire connections towards the right, the left or the top. In such a case, it can be useful to arrange the solder glass encapsulating material 140 on the whole surface area of the substrate 110, such that not only the semiconductor device 120 but at the same time all bond wires of the device 120 and contact terminals 125 are protected.

FIG. 3 shows a cross-sectional view of an embodiment of the present invention, wherein the device 120 is arranged on the substrate 110, and both the device 120 and the bond wires 130a and 130b are protected by the solder glass material 140, wherein the solder glass material 140 can protect the whole device (whole free surface) or leave a region 140′ exposed. This can, for example, be the case when the device 120 already has a sufficient protecting passivation, or access to the environment (e.g. in photo sensors, pressure sensors, etc.) is necessitated. Thus, the solder glass material 140 can separate the semiconductor device 120 along the lateral expansion of the substrate 110 from an external environment, such that, apart from incident radiation, for which the solder glass material 140 is transparent (e.g. light), no other harmful environmental influence, such as dust, humidity or air can limit the operating mode of the device 120. However, the solder glass material 140 can also be opaque for visible light or the UV range in order to decelerate, for example, the aging process of the chip.

In further embodiments it is also possible that the semiconductor device 120 is mounted or soldered to the substrate 110 via a further solder glass material 145. Thereby, the further solder glass material 145 serves as adhesive or soldering material generating a stable mechanical connection between the semiconductor device 120 and the substrate 110. The further solder glass material 145 can be selected such that the coefficient of thermal expansion of the further solder glass material 145 lies between the coefficient of thermal expansion of the substrate 110 (first coefficient of thermal expansion) and the coefficient of thermal expansion of the semiconductor device 120 (second coefficient of thermal expansion), such that the further solder glass material 145 acts at the same time as a buffer layer for reducing thermal stresses between the semiconductor device 120 and the substrate 110. The further solder glass material 145 can also be selected to be the same as the solder glass material 140—however it can also be deliberately selected differently for obtaining a better thermal adaptation, for example.

Again, the solder glass material 140 can be selected such that the coefficient of thermal expansion of the solder glass material 140 is adapted to the coefficient of thermal expansion of the bond wire 130 (third coefficient of thermal expansion) in connection with the coefficient of thermal expansion of the substrate 110 (and/or the terminal region 115) and the semiconductor device 120 (and/or the contact terminal 125). Generally, the terminal region 115 and the contact terminal 125 are formed so thin that their expansion mostly follows the thermal expansion of the substrate 110 or the semiconductor device 120, such that their expansion normally does not have any influence on the overall system. The bondpads frequently have the same material as the bond wires. In this case, it is also advantageous to select the coefficient of thermal expansion of the solder glass material 140 such that thermal stresses on the bond wire connection between the bond wire 130 and the contact terminal 125 and on the bond wire connection between the bond wire 130 and the terminal region 115 are minimized.

Different solder glass materials can thus serve, on the one hand, as solder glass encapsulating materials 140 with an adapted coefficient of thermal expansion and also as chip adhesive material (further solder glass material 145) for mounting a semiconductor device 120 to the substrate 110 such that higher temperature fluctuations, e.g. from room temperature up to 250° C. or successive cycles, can be handled without danger of damage or detachment of the device.

The coefficient of thermal expansion of the solder glass material 140 can be selected, for example, between the second and third coefficients of thermal expansion. It is also possible that the coefficient of thermal expansion lies within a tolerance range, wherein the limits of the tolerance range can, for example, be selected such that they differ by a first factor from the second or by a second factor from the third coefficient of thermal expansion or by a third factor from the average value, wherein the first and/or second and/or third factors can, for example, be 1/10, 1/5, 1/2, 2, 5 or 10.

In further embodiments of the present invention, the solder glass material 140 is deposited onto the substrate 110, wherein the substrate 110 comprises an oxidized surface or a passivation layer. Adhesion of the solder glass material 140 can be realized, for example, via the bond wires 130 or via the semiconductor device 120. In this way, for example, depositing the solder glass material 140 on the terminal region 115 and/or on the contact terminal 125 can result in an oxidation of the same (forming an oxide layer and/or a further oxide layer), wherein this results in adhesion of the solder glass material to the contact terminal 125 and the terminal region 115. Adhesion of the solder glass material 140 to the substrate 110 can also be obtained by oxidation of the substrate 110 (by forming an oxidation layer), wherein oxidation can occur during deposition or formation of the solder glass material 140.

With regard to the coefficients of thermal expansion, the following ranges or values can be stated exemplarily:

Chip (silicon): 2.0-3.5 ppm/K (10⁻⁶/K),

Substrate: 2.0-10 ppm/K

Bond wires
aluminum: 23.2 ppm/K,
gold: 14.2 ppm/K,
silver: 19.5 ppm/K,
platinum: 9.0 ppm/K and
tungsten: 4.5 ppm/K,
   wherein the substrate 110 can also comprise ceramics, such as Al₂O₃, MN (HTCC=high temperature cofired ceramics, LTCC=low temperature cofired ceramics). Further, the substrate 110 can also comprise alloys, such as invar or NiCo. The stated values relate to ideal values. In practice, the metals do not exist in a pure form and thus, depending on the impurities, or in possible mixtures of different metals (alloys), these values can vary (for example by +/−30%). Thus, bond wires having an intermediate value for the coefficient of thermal expansion in a range of 4 to 25 ppm/K are also possible.

The coefficient of thermal expansion of the solder glass material 140 can be selected such that it is close to the coefficient of thermal expansion of the substrate 110 or between the CTE of the substrate and the CTE of the bond wire. The melting temperature or softening temperature should not be above 800° C., since from this temperature range onwards chips (device 120) exhibit malfunctions or malfunctions can occur. The malfunctions result, for example, from a change of dopings or doping profiles (e.g. activating thermal donators) or from deformations or detachment of metallizations on/in the chip. The solder glass material 140 should be sufficiently soft during heating such that thermal stresses can be compensated. On the other hand, there should still be firm support and firm fixation at normal working temperatures.

The solder glass material 140 can, for example, be generated with a layer thickness of at least 100 μm or 500 μm or 800 pm or 1 mm or 2 mm, and can hermetically enclose both the bond wire 130 or all bond wires and the semiconductor device 120. The layer thickness of the solder glass material 140 can also be in a range, for example, between 10 μm and 5 mm or between 100 μm and 1 mm.

In contrast to common methods for protecting bond wires using silicone, epoxy or polyamide, according to an inventive method using a solder glass material as a glob top mass, in particular a used material or composition can be adapted with regard to the coefficients of thermal expansion of the individual materials of the components. Thereby, enormous stresses due to more heavily fluctuating temperatures between the bond wires, the substrate 110 and the device can be compensated. In contrast to conventional methods, a stable electrical connection of the bond wire 130 to the substrate 110 or the bond wire 130 to the device is ensured across a much larger temperature range (for example for temperature fluctuations up to more than 200° C.). Thus, the danger of total failure of the device is significantly reduced.

Devices can, for example, have a silicon chip, such that the coefficient of thermal expansion of the chip (device) is at approximately 2.5 ppm/K (ppm=parts per million=10⁻⁴%). On the other hand, a typical bond wire can have a coefficient of thermal expansion in a range between 10 and 25 ppm/K, while used materials for a convention glob top mass frequently have a value of up to ten or a hundred times higher for the coefficient of thermal expansion (compared to a silicon chip). These different coefficients of thermal expansion, however, do not present a large problem for temperatures in a range of up to 120° C. At temperatures above 120° C., however, the large difference between the coefficients of thermal expansion between the used materials (glob top material, chip 120 and bond wire 130) can result in an interruption of the electric bond wire connection within several hours. The lifetime of the connection depends significantly on the temperature or the temperature fluctuations, respectively, and on the time periods within which the temperatures fluctuate. At a temperature of 250° C., when using conventional materials, almost all electrical connections can be destroyed after several days or cycles (RT−250° C., RT=room temperature). These problems of conventional encapsulation have been overcome by inventive encapsulations of the bond wires.

While this invention has been described in terms of several advantageous embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. Circuitry, comprising:
a substrate (110) comprising a terminal region (115), the substrate material having a first coefficient of thermal expansion;
a semiconductor device (120) comprising a contact terminal (125), the device material having a second coefficient of thermal expansion;
a bond wire (130) connecting the terminal region (115) to the contact terminal (125), the bond wire material having a third coefficient of thermal expansion; and
a solder glass encapsulating material (140) mounted to the semiconductor device (120) with the bond wire (130), such that at least the bond wire (130) is hermetically enclosed,
wherein the solder glass encapsulating material (140) has a coefficient of thermal expansion and is composite such that the coefficient of thermal expansion is adjusted to a predefined value with regard to the second and third coefficients of thermal expansion.

2. Circuitry according to claim 1, wherein the predefined value lies between the second and third coefficients of thermal expansion.

3. Circuitry according to one of the previous claims, wherein the semiconductor device (120) and the terminal region (115) are formed on a main surface of the substrate (110).

4. Circuitry according to one of the previous claims, wherein a further solder glass material (145) is arranged between the semiconductor device (120) and the substrate (110), and the further solder glass material (145) establishes a mechanical connection between the substrate (110) and the semiconductor device (120), wherein the further solder glass material (145) has a further coefficient of thermal expansion, which has a further predefined value with regard to the first and second coefficients of thermal expansion.

5. Circuitry according to claim 4, wherein the further solder glass-encapsulating material (145) has a different material composition than the solder glass encapsulating material (140).

6. Circuitry according to one of the previous claims, wherein the semiconductor device (120) comprises a further contact terminal and wherein the substrate comprises a further terminal region, wherein the further terminal region is connected to the further contact terminal via a further bond wire, wherein the solder glass encapsulating material (140) hermetically encloses the semiconductor device (120) and the further bond wire.

7. Circuitry according to one of the previous claims, wherein the solder glass encapsulating material (140) has at least a layer thickness of 100 μm or 500 μm or 800 μm or 1 mm or 2 mm.

8. Circuitry according to one of the previous claims, wherein the predefined value lies between 0.2 ppm/K and 27 ppm/K or between 1.5 ppm/K and 8 ppm/K, or wherein the predefined value and the second coefficient of thermal expansion form a ratio lying between 1:10 and 10:1 or between 1:5 and 5:1 or preferably between 1:2 and 2:1, and/or the predefined value and the third coefficient of thermal expansion form a further ratio lying between 1:10 and 10:1 or between 1:5 and 5:1 or preferably between 1:2 and 2:1.

9. Method for producing a glass-encapsulated bond wire connection, comprising:
providing a substrate (110) comprising a terminal region (115), the substrate material having a first coefficient of thermal expansion;
arranging a semiconductor device (120) comprising a contact terminal (125) on the substrate (110), the device material having a second coefficient of thermal expansion;
connecting the contact terminal (125) to the terminal region (115) with a bond wire (130), the bond wire material having a third coefficient of thermal expansion; and
forming a solder glass encapsulating material (140) such that at least the bond wire (130) is hermetically enclosed,
wherein the solder glass encapsulating material (140) has a coefficient of thermal expansion and is composite such that the coefficient of thermal expansion is adjusted to a predefined value with regard to the second and third coefficients of thermal expansion.

10. Method according to claim 9, wherein the step of forming the solder glass encapsulating material (140) is performed such that the predefined value lies between the second and third coefficients of thermal expansion.

11. Method according to claim 9, wherein the step of depositing a solder glass encapsulating material (140) comprises
depositing a powder;
liquifying the powder, and
annealing for obtaining a solidified solder glass encapsulating material (140).

12. Method according to one of claims 9 to 11, wherein the step of depositing the solder glass encapsulating material (140) comprises depositing a liquid or paste-like solder glass encapsulating starting material on the bond wire (130) and annealing the liquid solder glass encapsulating starting material for obtaining the solder glass encapsulating material (140).

13. Method according to one of claims 9 to 12, wherein in the step of forming the solder glass encapsulating material (140) the solder glass encapsulating material (140) is formed in a predefined thickness of at least 100 μm or at least 1 mm.
